(19) United States
(12) Patent Application Publication
(10) Pub. No.: US 2026/0305410 A1
(43) Pub. Date: Oct. 1, 2026

(54) SEMICONDUCTOR PACKAGES WITH SEPARATELY PLATED METAL PILLARS

(71) Applicant: TEXAS INSTRUMENTS INCORPORATED, Dallas, TX (US)

(72) Inventors: Jarevic CAYABYAB, Pangasinan (PH); Jamel CAYABYAB, Pangasinan (PH)

(21) Appl. No.: 19/096,118

(22) Filed: Mar. 31, 2025

(51) Int. Cl. H10W 70/65; H10W 90/00; H10W 72/00; H10W 72/20; H10W 74/10

(52) U.S. Cl. CPC H10W 70/65; H10W 90/701; H10W 72/01235; H10W 72/01255; H10W 72/222; H10W 72/223; H10W 72/232; H10W 72/234; H10W 72/235; H10W 72/237; H10W 72/248; H10W 72/252; H10W 72/255; H10W 74/10; H10W 90/724

(57) ABSTRACT

A method includes forming metal pads on a device side of a semiconductor wafer in which circuitry and metal vias are formed, where the metal pads physically contact the metal vias. The method includes applying a dielectric layer on the metal pads, forming openings in the dielectric layer above the metal pads, depositing a seed layer on the dielectric layer and the metal pads, and plating a first set of metal pillars on a first set of the metal pads and separately plating a second set of metal pillars on a second set of the metal pads such that the first set of metal pillars and the second set of metal pillars have distal ends that are coplanar. The first and second sets of metal pillars have differing shapes in the top-down view.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such integrated circuits on a wafer is called fabrication. After wafer fabrication, the wafer is cut into multiple pieces, called semiconductor dies, with each die containing one or more of the integrated circuits. The cutting, or sawing, of the wafer into individual dies is called singulation. An individual die may then be coupled to a substrate or die pad. The resulting structure is subsequently covered with a mold compound to produce a package.

### SUMMARY

A method includes forming metal pads on a device side of a semiconductor wafer in which circuitry and metal vias are formed, where the metal pads physically contact the metal vias. The method includes applying a dielectric layer on the metal pads, forming openings in the dielectric layer above the metal pads, depositing a seed layer on the dielectric layer and the metal pads, and plating a first set of metal pillars on a first set of the metal pads and separately plating a second set of metal pillars on a second set of the metal pads such that the first set of metal pillars and the second set of metal pillars have distal ends that are coplanar. The first and second sets of metal pillars have differing shapes in the top-down view.

A semiconductor package includes a semiconductor die having a device side in which circuitry is formed, a first set of metal pillars on the device side of the semiconductor die having a first structural grain pattern, and a second set of metal pillars on the device side of the semiconductor die having a second structural grain pattern. The second structural grain pattern is different from the first structural grain pattern. The package includes a set of conductive terminals coupled to the first and second sets of metal pillars by solder bumps. The set of conductive terminals faces the device side of the semiconductor die. The package includes a mold compound covering the semiconductor die, the first and second sets of metal pillars, and the set of conductive terminals.

### BRIEF DESCRIPTION OF THE DRAWINGS

FIG. 1 is a flow diagram of a method for manufacturing a semiconductor package having separately plated metal pillars, in accordance with various examples.

FIGS. 2A1, 2A2, 2B1, 2B2, 2C1, 2C2, 2D1, 2D2, 2E1, 2E2, 2F1, 2F2, 2G1, 2G2, 2H1, 2H2, 2I1, 2I2, 2J1, 2J2, 2K1, 2K2, 2L1, 2L2, 2M1, 2M2, AND 2M3 are a process flow depicting the manufacture of a semiconductor package having separately plated metal pillars, in accordance with various examples.

FIG. 3 is a block diagram of an electronic device including a semiconductor package having separately plated metal pillars, in accordance with various examples.

### DETAILED DESCRIPTION

Electroplating is a deposition process in which a metal layer is formed on a conductive substrate through the reduction of metal ions from an electrolyte solution. This process is driven by an applied electric potential, which facilitates ion migration toward the cathode, where metal atoms are deposited. Electroplating is widely used in semiconductor packaging, printed circuit board fabrication, and microelectromechanical systems (MEMS) manufacturing to create conductive interconnections, enhance surface properties, and enable advanced device architectures. The process relies on precise control of current density, electrolyte composition, and deposition parameters to achieve uniform coatings with specific thicknesses and material properties. In applications involving patterned photoresist layers, metal deposition occurs selectively in exposed regions, forming structures such as copper pillars or redistribution layers. The geometry of these features, along with electrochemical and transport phenomena, influences the final plated structure, often leading to variations in deposition rates across different feature sizes and locations.

Electroplating rates in cavities of different sizes and shapes vary primarily due to differences in local current density, mass transport effects, edge and proximity effects, and additive adsorption. The current density at each plating site follows Ohm’s Law, where the total current is distributed across the available conductive area. Larger cavities exhibit lower local current density because the current is spread over a greater surface area, leading to a reduced plating rate. Conversely, smaller cavities experience a higher local current density, which results in a higher plating rate. Irregularly shaped cavities further affect current distribution, as electric field concentration at edges or corners can increase the localized plating rate. These variations in current density lead to differential deposition rates across the patterned surface, causing plated pillars to form at different heights.

Mass transport effects also contribute to plating rate discrepancies by influencing the availability of metal ions at the electrode surface. In larger cavities, metal ion diffusion occurs over a longer distance, leading to localized depletion and a slower deposition rate unless solution agitation sufficiently replenishes ions. Smaller cavities allow more efficient replenishment due to shorter diffusion paths, supporting a higher plating rate. Edge and proximity effects further impact the process, as electric field interactions between closely spaced features alter local current distribution. Plating solutions contain levelers, brighteners, and suppressors that adsorb differently on surfaces based on feature size, further modulating deposition rates. These combined effects result in non-uniform plating, where structures with different geometries exhibit varied growth rates, ultimately affecting the coplanarity of electroplated features.

Such plating techniques are useful to form metal pillars in semiconductor packages. These metal pillars provide electrical pathways between semiconductor die circuitry and solder bumps, which, in turn, may be coupled to printed circuit boards (PCBs). Such metal pillars may also provide structural support within the semiconductor package. When the metal pillars have differing heights, such as for the reasons described above, yield drops significantly, because the metal pillars can be difficult to wet, and the resulting solder joints are vulnerable to cracking, breaking, and detachment.

This description presents various examples of a semiconductor package that includes multiple metal pillars which, although differently sized and/or shaped, have distal ends that are coplanar or approximately coplanar with each other. This coplanarity is achieved by plating metal pillars of the same size and shape independently of the remaining pillars, which have different sizes and shapes. For example, if metal pillars of differing horizontal cross-sectional shapes (e.g., circular and oval) are to be formed in the same semiconductor package, a first photoresist patterned to form the circular metal pillars is used to plate the circular metal pillars first, and then, after the circular metal pillars are formed, a second photoresist patterned to form the oval metal pillars is used to plate the oval metal pillars. Because the circular cavities in the first photoresist are of uniform size and shape, the circular metal pillars plated inside those cavities will form at the same rate and will have the same height, meaning that the distal ends of these circular metal pillars will be coplanar with each other. Similarly, because the oval cavities in the second photoresist are of uniform size and shape, the oval metal pillars plated inside those cavities will form at the same rate and will have the same height, meaning that the distal ends of these oval metal pillars will be coplanar with each other. Because the circular metal pillars form (i.e., vertically grow) at a different rate than the oval metal pillars, the circular metal pillars are plated for a different duration of time than the oval metal pillars. For example, if the circular metal pillars plate faster than the oval metal pillars, then the duration of time for plating the circular metal pillars is shorter than the duration of time for plating the oval metal pillars. By controlling plating duration in this way, the heights of the various metal pillars can be controlled to be identical. This means that the distal ends of the various metal pillars are coplanar or approximately coplanar, regardless of pillar shape and/or size. Because the metal pillars are of uniform height irrespective of shape and/or size, the solder wetting and solder joint reliability challenges described above are mitigated, thereby substantially increasing manufacturing yield.

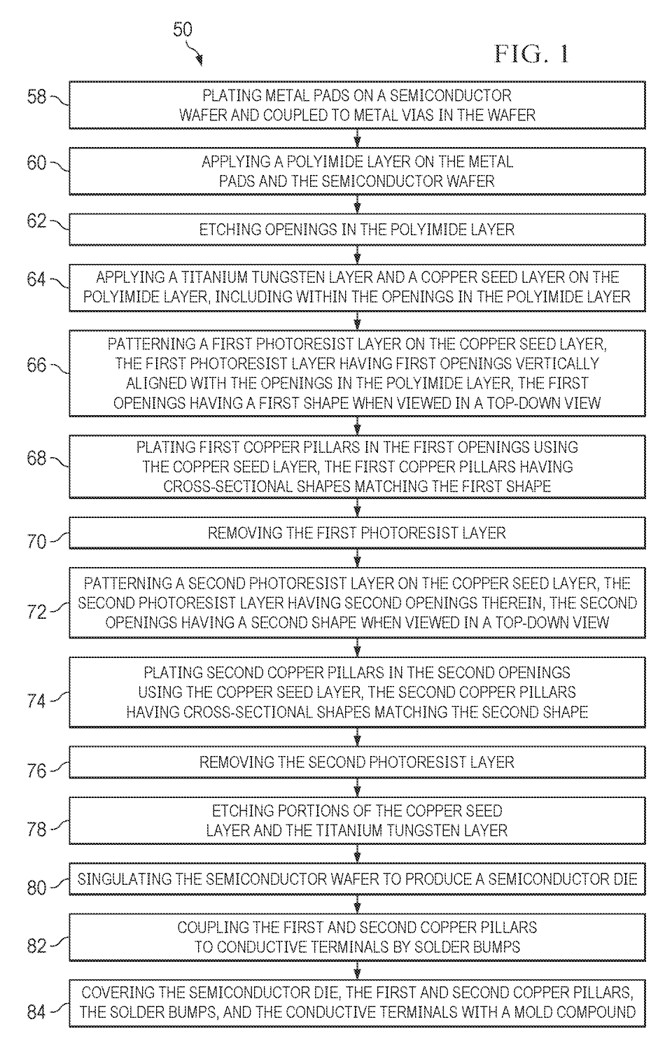

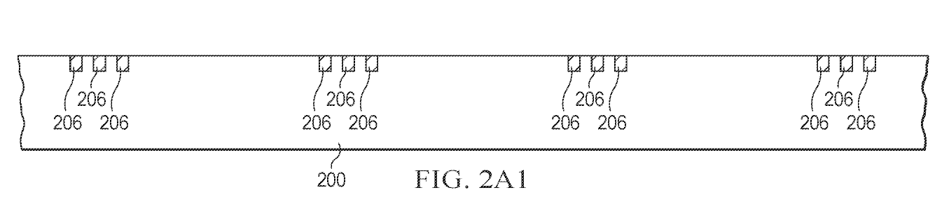

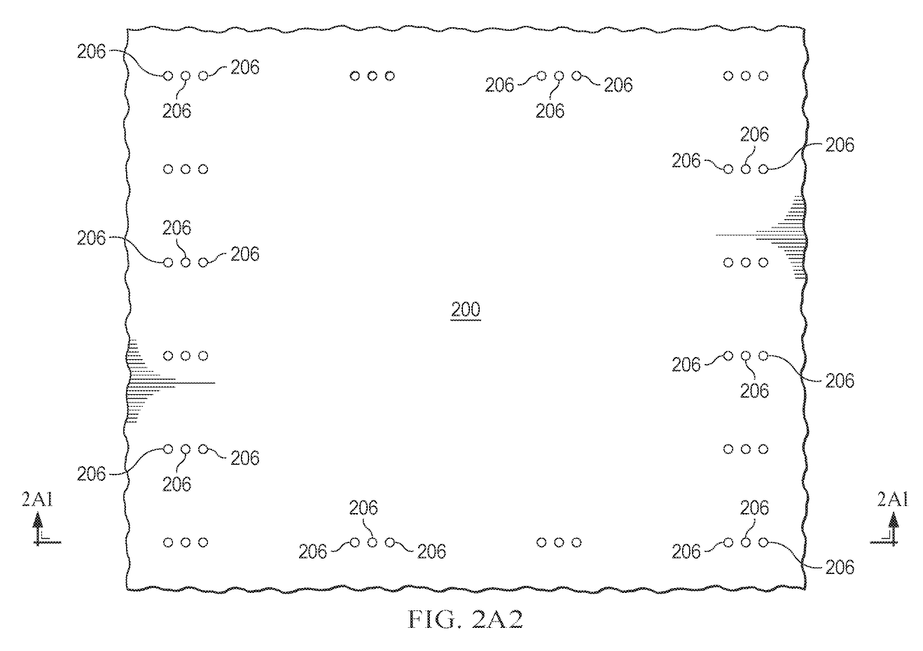

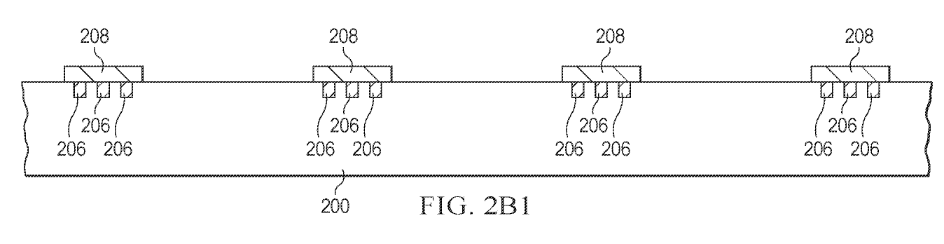

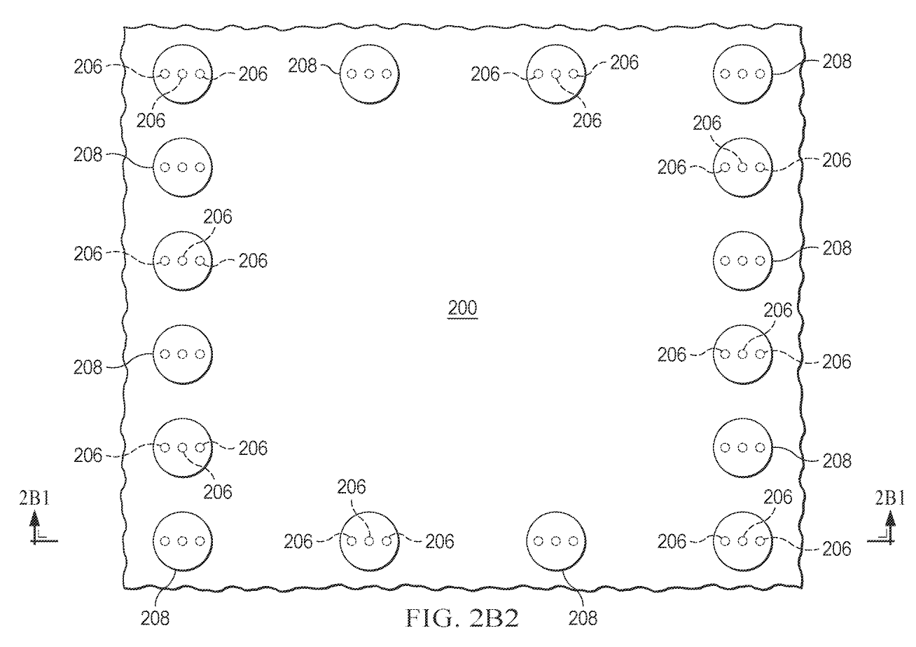

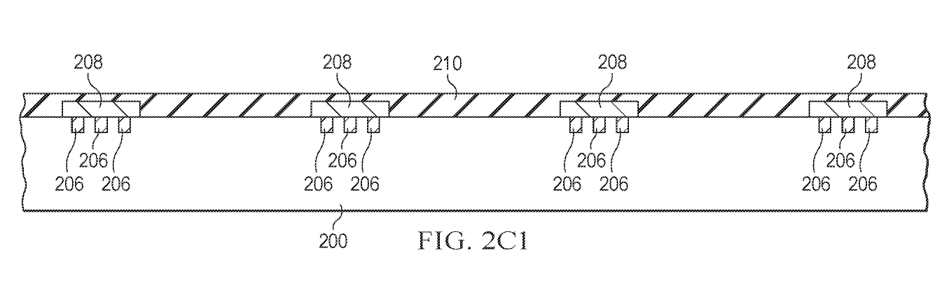

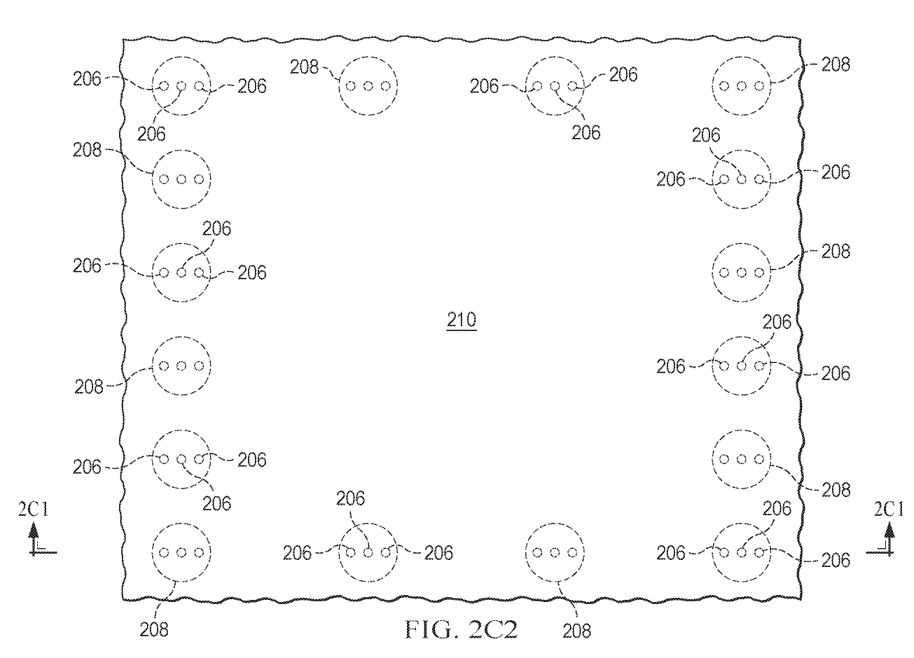

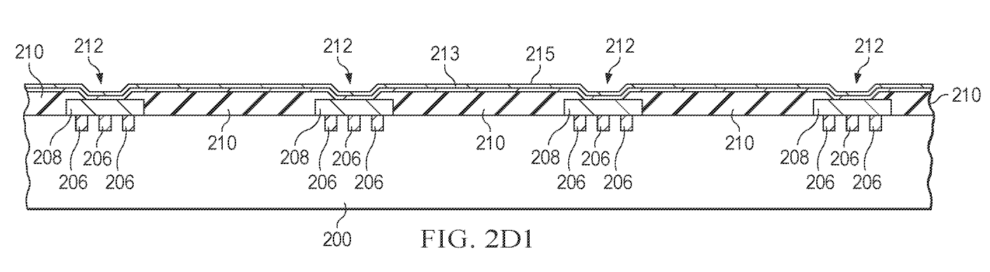

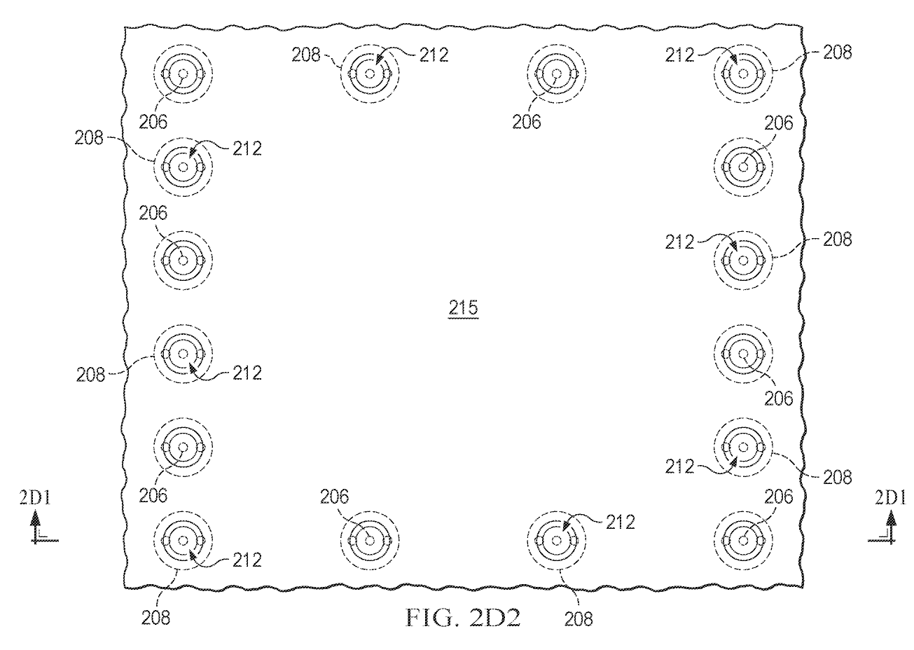

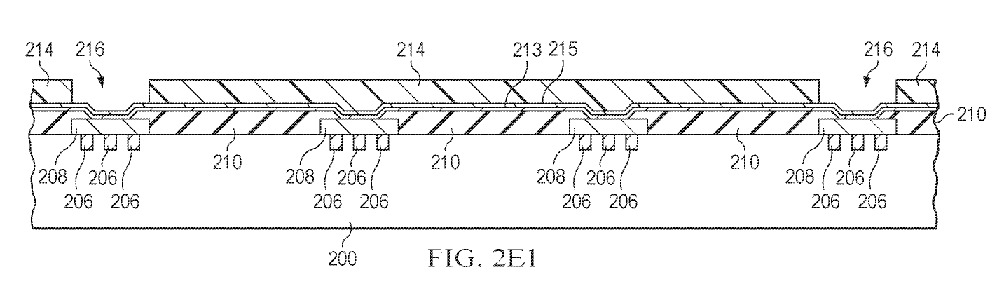

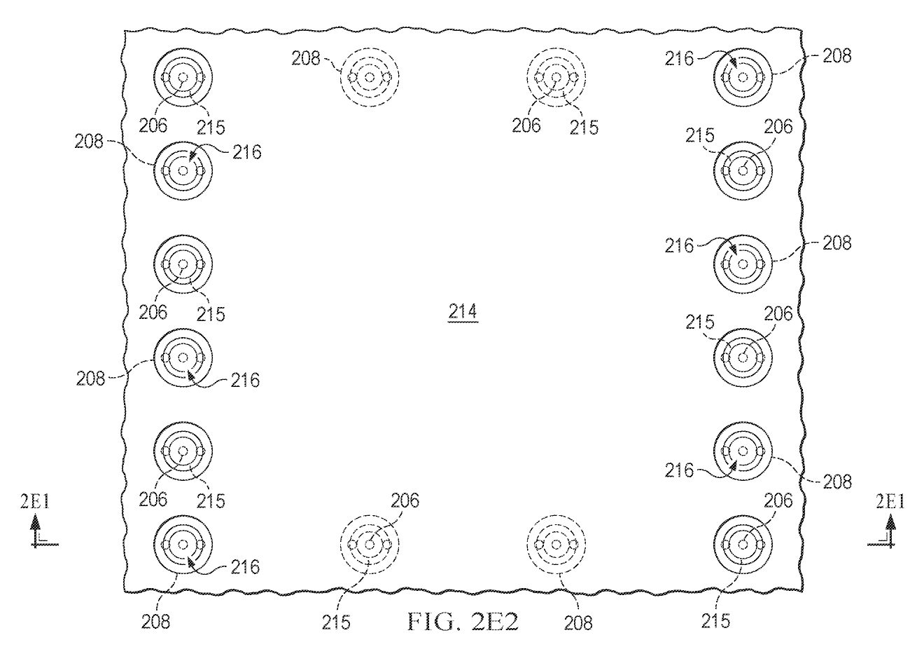

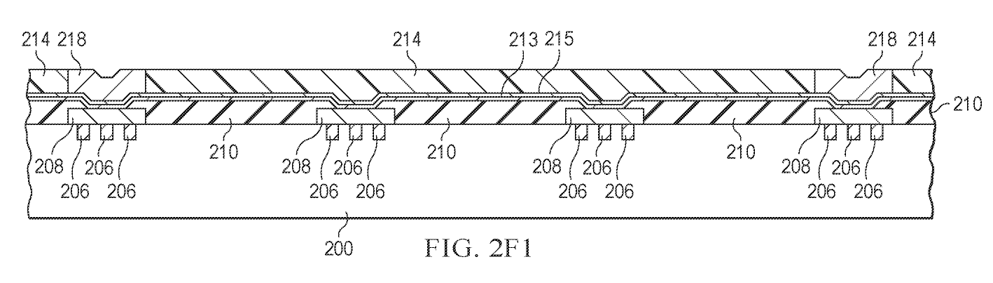

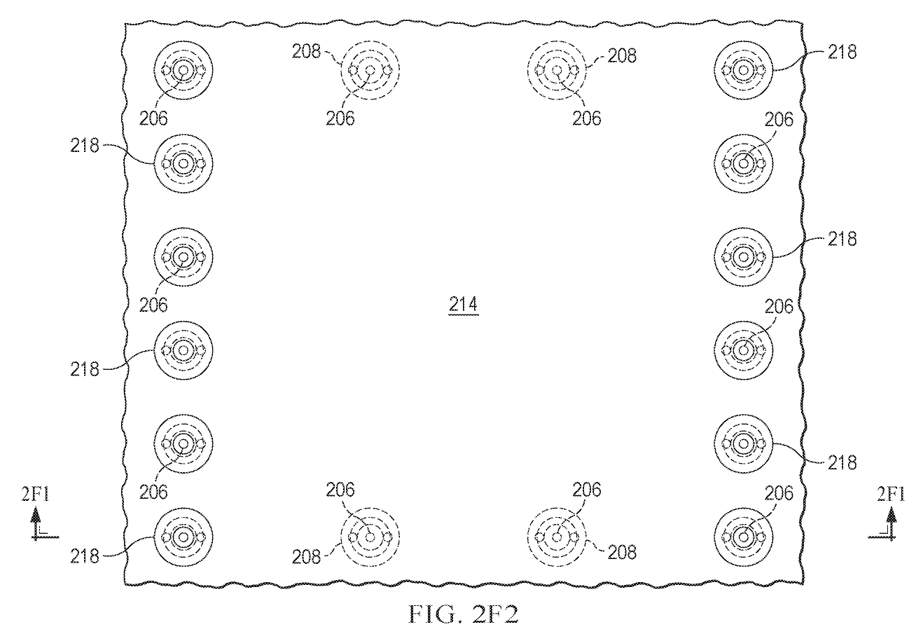

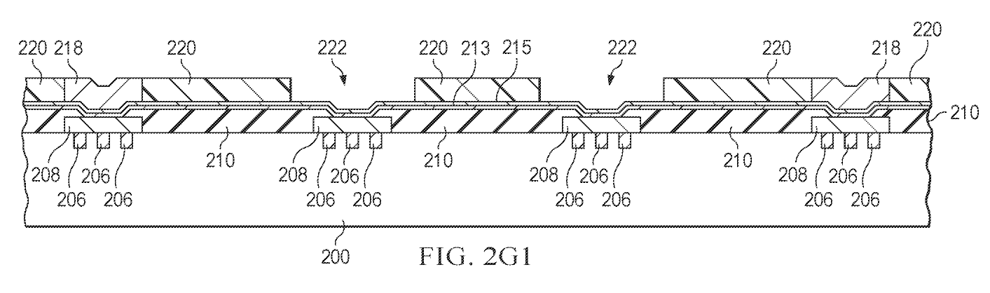

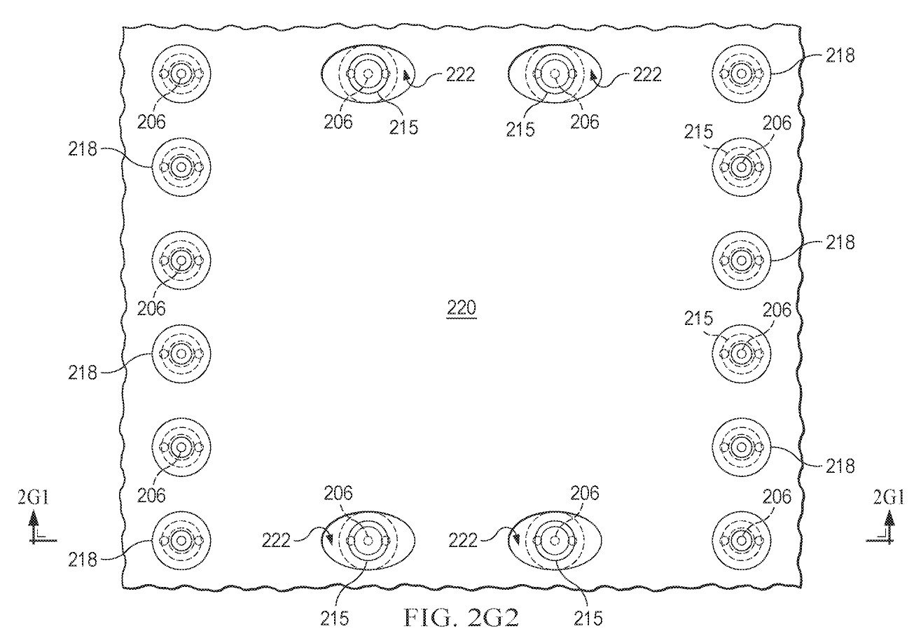

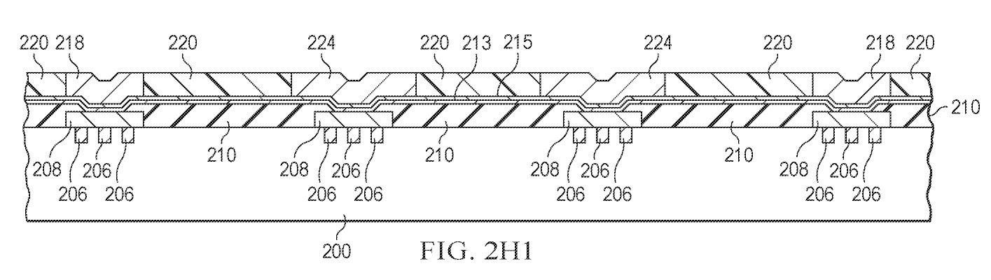

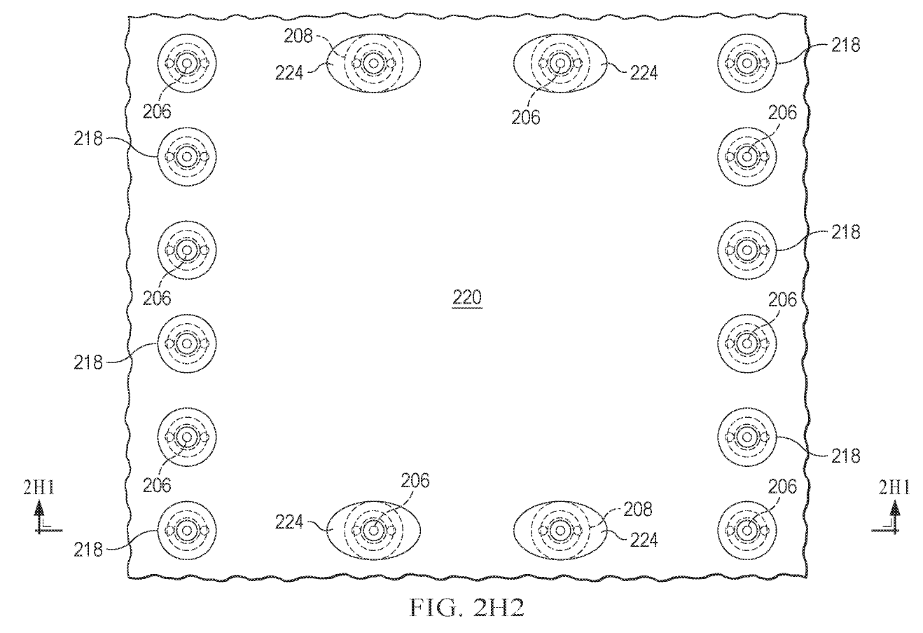

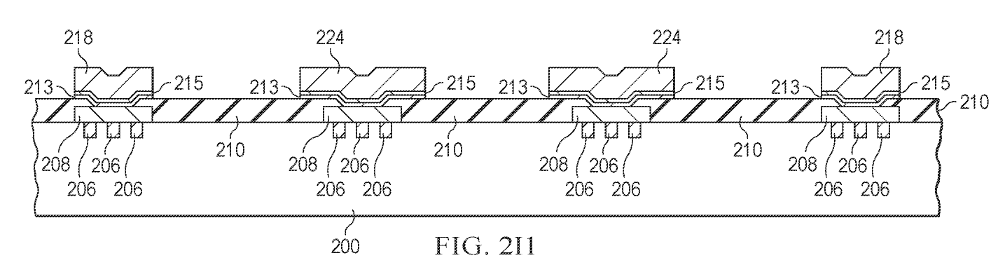

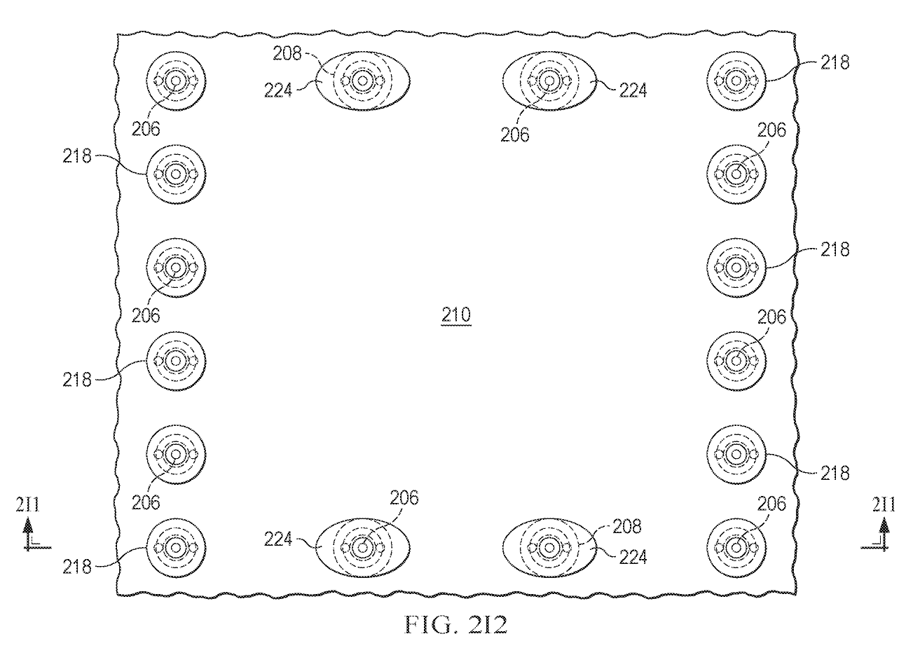

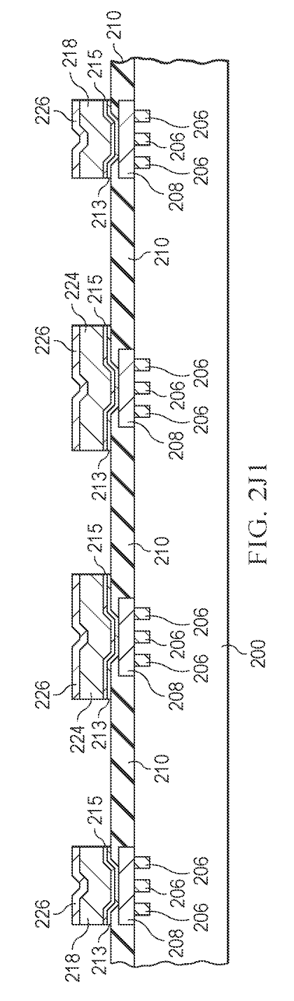

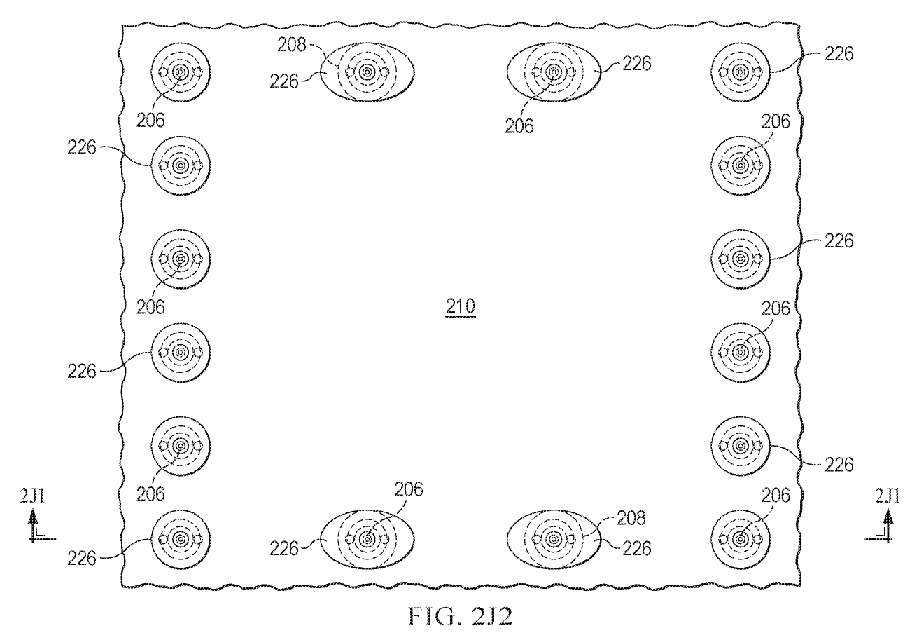

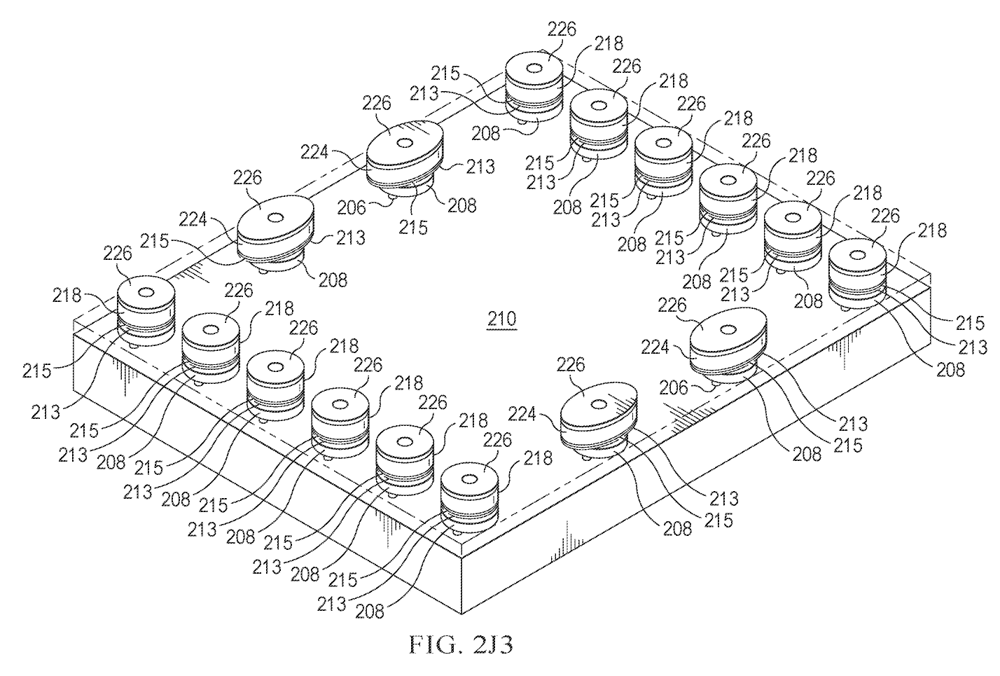

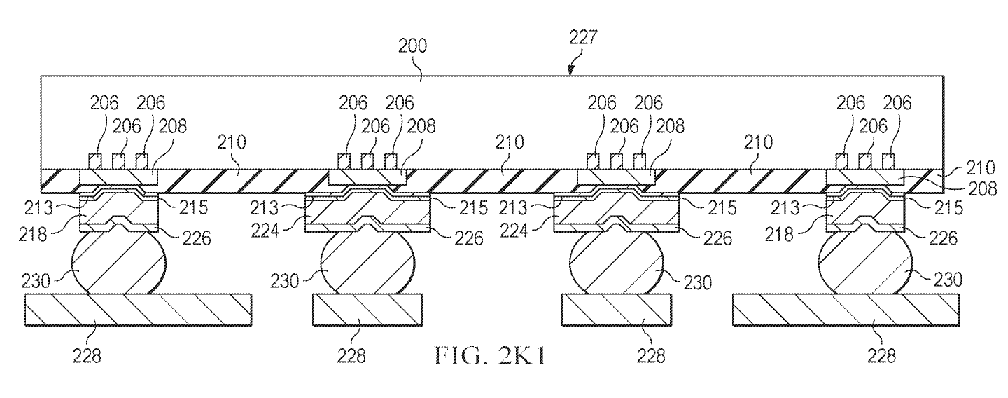

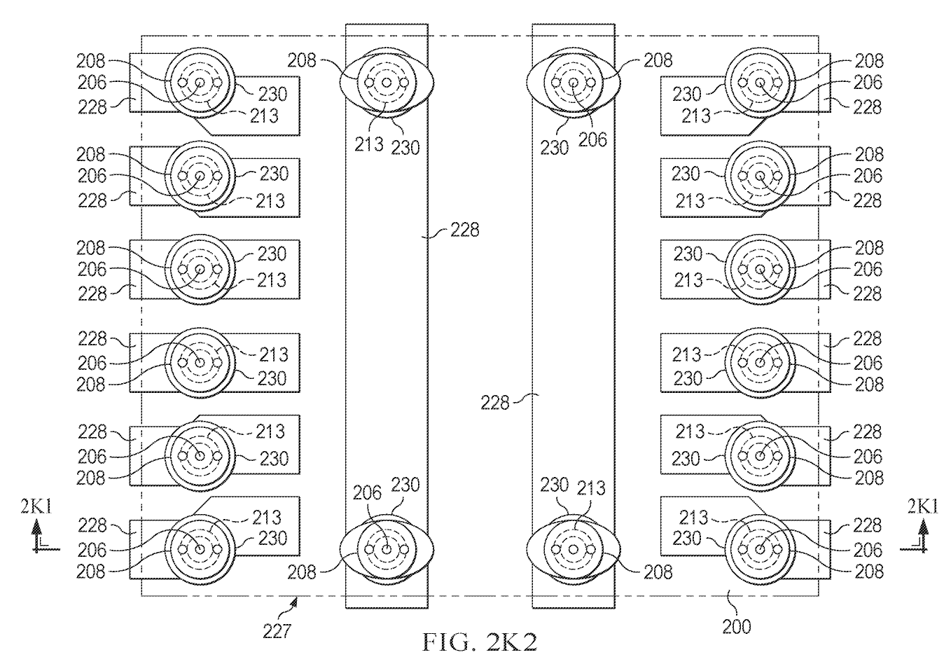

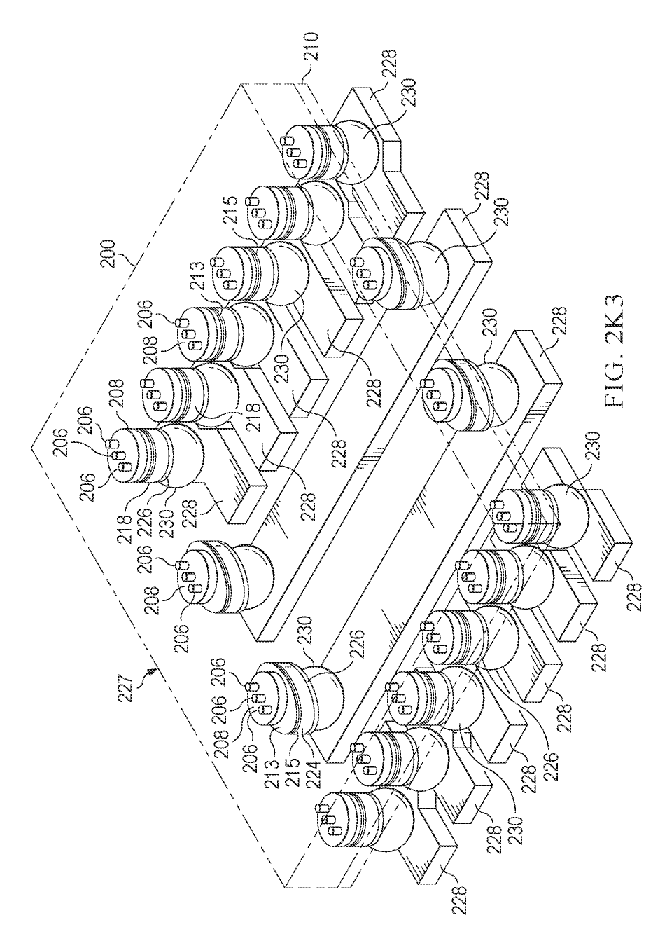

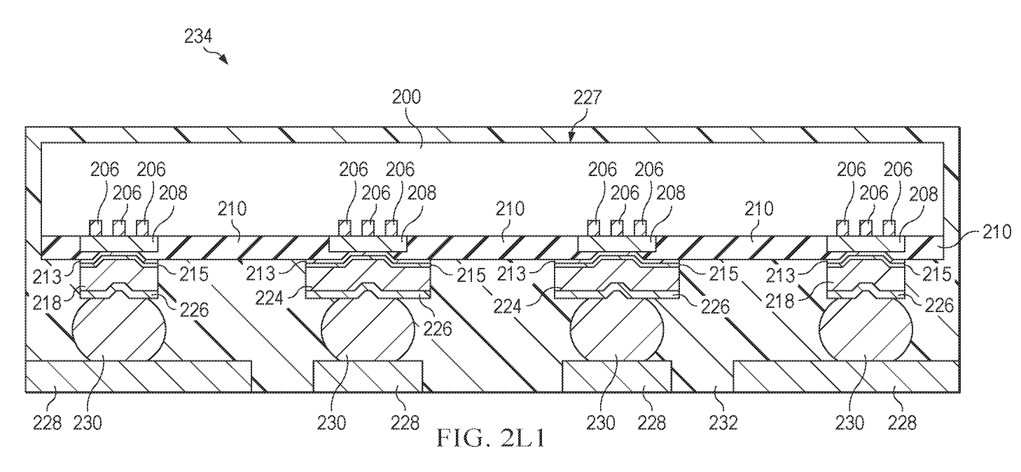

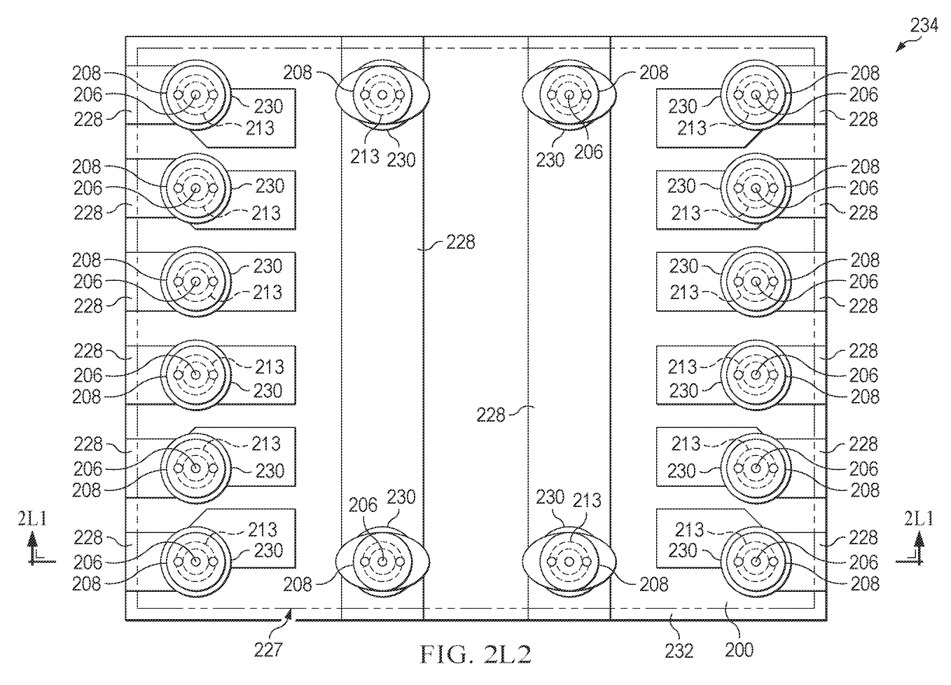

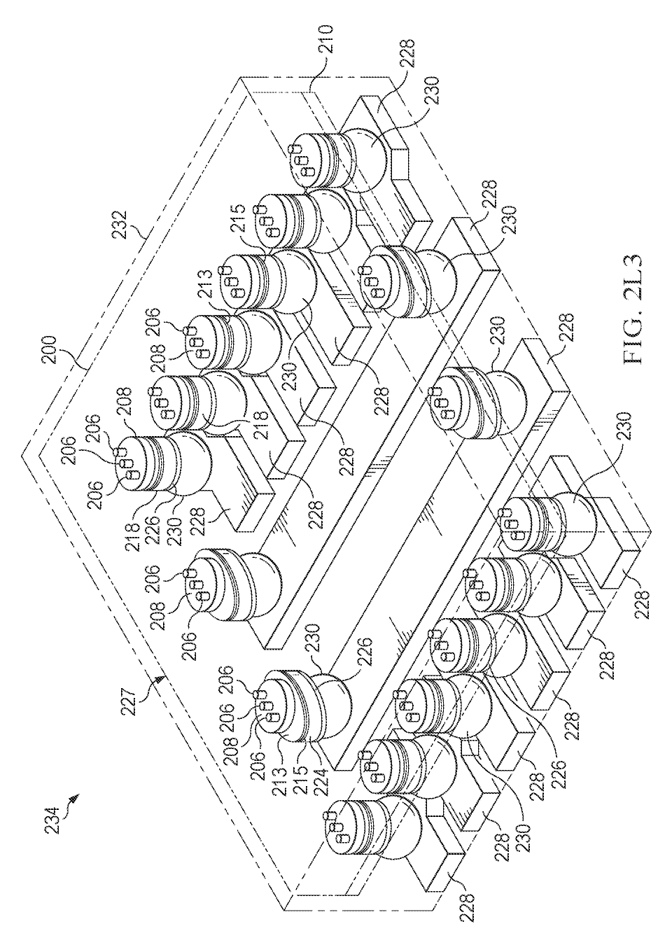

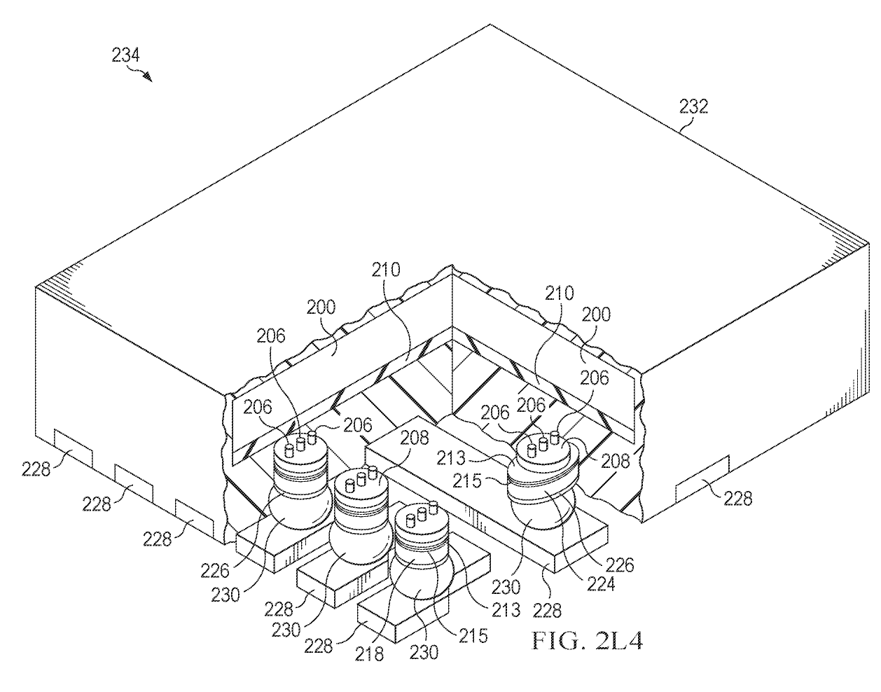

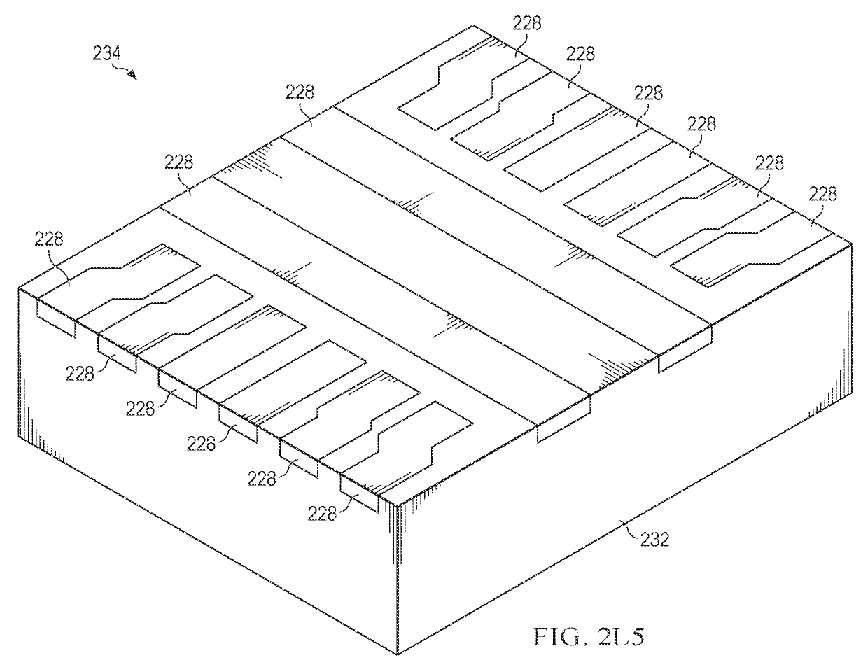

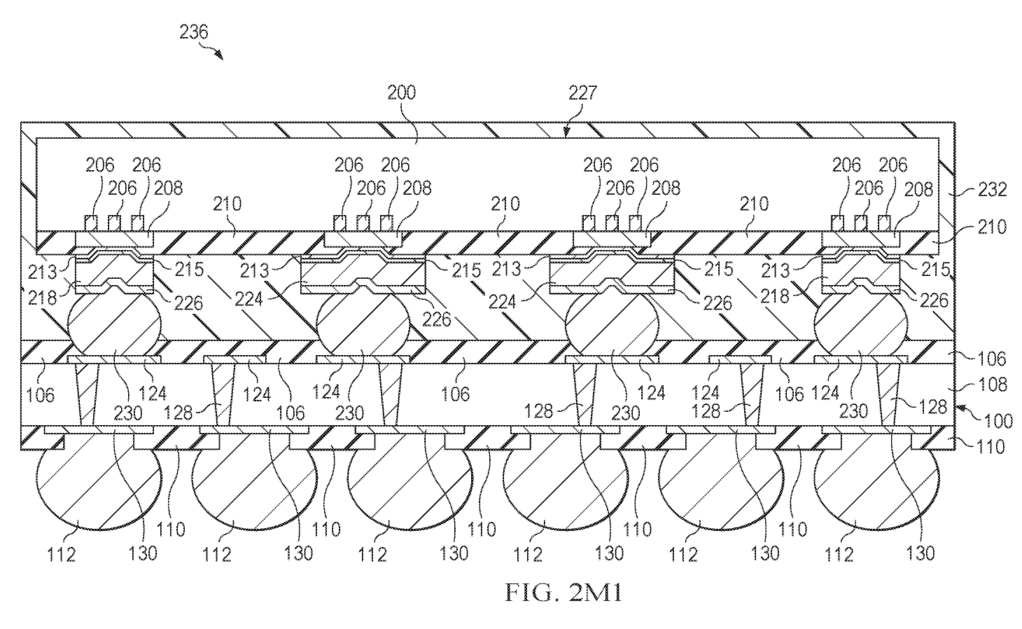

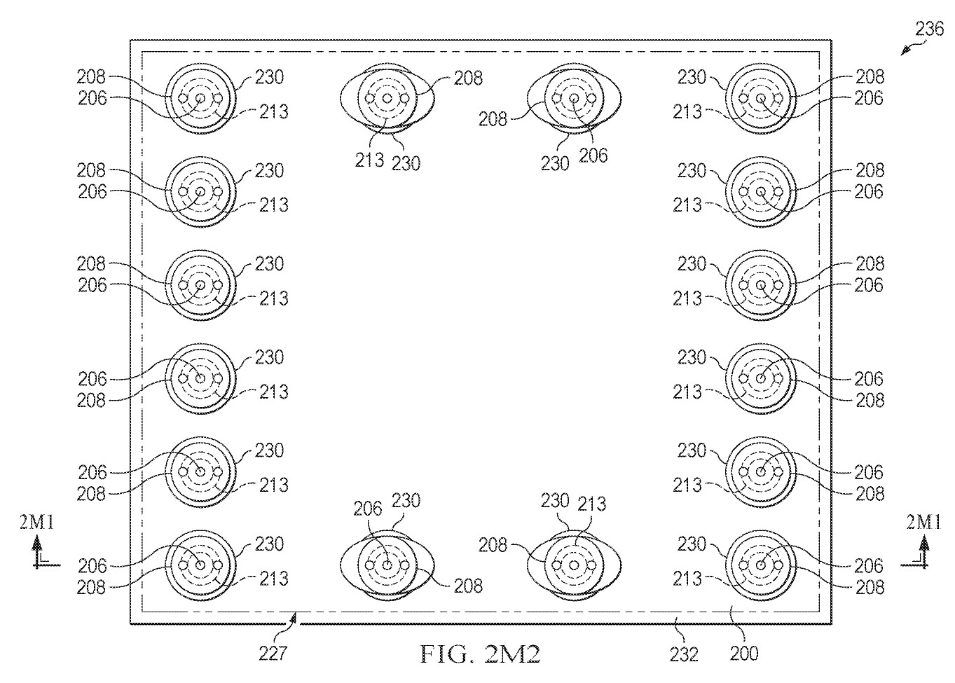

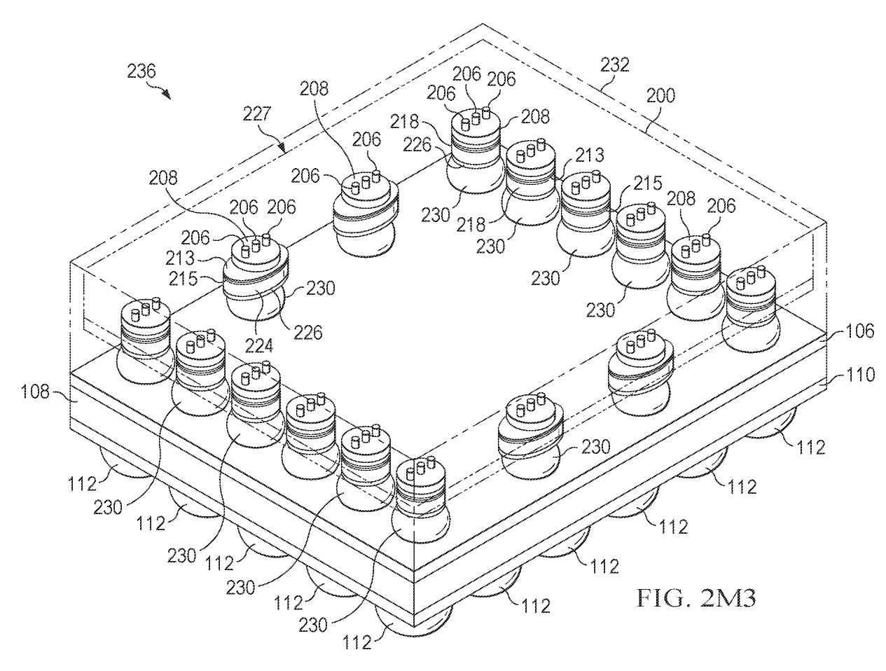

FIG. 1 is a flow diagram of a method 50 for manufacturing a semiconductor package having separately plated metal pillars, in accordance with various examples. FIGS. 2A1, 2A2, 2B1, 2B2, 2C1, 2C2, 2D1, 2D2, 2E1, 2E2, 2F1, 2F2, 2G1, 2G2, 2H1, 2H2, 2I1, 2I2, 2J1, 2J2, 2K1, 2K2, 2L1, 2L2, 2M1, 2M2, and 2M3 are a process flow depicting the manufacture of a semiconductor package having separately plated metal pillars, in accordance with various examples. Accordingly, FIGS. 1 and 2A1-2M3 are now described in parallel with each other.

The method 50 includes plating metal pads on a semiconductor wafer and coupled to metal vias in the wafer (58). FIGS. 2A1 and 2A2 are profile cross-sectional and top-down views of a semiconductor wafer 200 having metal vias 206 (e.g., in a top metal layer of the wafer 200). FIGS. 2B1 and 2B2 are profile cross-sectional and top-down views of the structure of FIGS. 2A1 and 2A2, except that metal pads 208 are on top of the semiconductor wafer 200, contacting the metal vias 206, as shown. A copper seed layer (not expressly shown) may be applied and photolithography and plating techniques are used to form the metal pads 208, and then the portions of the copper seed layer not below the metal pads 208 are etched away. The metal pads 208 have thicknesses ranging from 4 microns to 25 microns, with a thickness below this range being disadvantageous because of unacceptably poor current carrying ability, and with a thickness above this range being disadvantageous because of significantly diminished improvements in current carrying ability.

The method 50 includes applying a polyimide layer on the metal pads and on the semiconductor wafer (60). FIGS. 2C1 and 2C2 are profile cross-sectional and top-down views of the structure of FIGS. 2B1 and 2B2, except that a polyimide layer 210 physically contacts and covers the metal pads 208 and the semiconductor wafer 200.

The method 50 includes etching openings in the polyimide layer (62). FIGS. 2D1 and 2D2 are profile cross-sectional and top-down views of the structure of FIGS. 2C1 and 2C2, except that openings 212 are formed in a top surface of the polyimide layer 210. In examples, the openings 212 are formed using a suitably patterned photoresist (not expressly shown) and a suitable etching technique. The photoresist is then stripped away. The openings 212 expose top surfaces of the metal pads 208. The method 50 also includes applying a titanium tungsten layer and a copper seed layer on the polyimide layer, including within the openings in the polyimide layer (64). FIGS. 2D1 and 2D2 depict a titanium tungsten layer ( TiW) 213 physically contacting a top surface of the metal pads 208 and polyimide layer 210, and a copper seed layer 215 physically contacting a top surface of the TiW 213, as shown.

The method 50 includes patterning a first photoresist layer on the copper seed layer (66). The first photoresist layer has first openings vertically aligned with the openings in the polyimide layer (66). The first openings have a first shape when viewed in a top-down view (66). FIGS. 2E1 and 2E2 are profile cross-sectional and top-down views of the structure of FIGS. 2D1 and 2D2, except that a patterned photoresist layer 214 physically contacts the top surface of the structure of FIGS. 2D1 and 2D2. The patterned photoresist layer 214 includes openings 216. The openings 216 are vertically aligned with some of the openings 212, as shown. The openings 216 have a horizontal area that is larger than that of the respective openings 212, as shown. In the top-down view, the openings 216 appear circular, meaning that the openings 216 have circular horizontal cross-sections. Other shapes, such as triangles, rectangles, and other polygons, ovoid shapes, etc. are contemplated and included in the scope of this disclosure. The combined depths of the openings 212 and 216 is the same as the desired height of each of the metal pillars that will subsequently be plated within the openings 212 and 216.

The method 50 includes plating first copper pillars in the first openings using the copper seed layer (68). The first copper pillars have cross-sectional shapes matching the first shape (68). FIGS. 2F1 and 2F2 are profile cross-sectional and top-down views of the structure of FIGS. 2E1 and 2E2, except that metal pillars 218 (e.g., copper pillars) are plated (e.g., electroplated) within the openings 212 and 216. The horizontal cross-sectional shape of the metal pillars 218 is circular, because the horizontal cross-sectional shape of the openings 216 is circular. The various metal pillars 218 plated in the openings 216 are plated at the same rate, meaning that at any given time, the metal pillars 218 have the same height. The total amount of time to plate the metal pillars 218 such that the distal (i.e., top) ends of the metal pillars 218 are approximately flush with the top surface of the patterned photoresist layer 214 is defined herein as time t₁. The method 50 includes removing the first photoresist layer (70).

The method 50 includes patterning a second photoresist layer on the copper seed layer (72). The second photoresist layer has second openings (72). The second openings have a second shape when viewed in a top-down view (72). FIGS. 2G1 and 2G2 are profile cross-sectional and top-down views of the structure of FIGS. 2F1 and 2F2, except that a patterned photoresist layer 220 having multiple openings 222 physically contacts the top surface of the structure shown in FIGS. 2F1 and 2F2. The openings 222 are vertically aligned with some of the openings 212, as shown. The openings 222 have a horizontal area that is larger than that of the respective openings 212, as shown. In the top-down view, the openings 222 appear oval, meaning that the openings 222 have ovoid horizontal cross-sections. Other shapes, such as triangles, rectangles, and other polygons, circular shapes, etc., are contemplated and included in the scope of this disclosure. The combined depths of the openings 212 and 222 is the same as the desired height of each of the metal pillars that will subsequently be plated within the openings 212 and 222.

The method 50 includes plating second copper pillars in the second openings using the copper seed layer (74). The second copper pillars have cross-sectional shapes matching the second shape (74). FIGS. 2H1 and 2H2 are profile cross-sectional and top-down views of the structure of FIGS. 2G1 and 2G2, except that metal pillars 224 (e.g., copper pillars) are plated (e.g., electroplated) within the openings 212 and 222. The horizontal cross-sectional shape of the metal pillars 224 is oval, because the horizontal cross-sectional shape of the openings 222 is oval. The various metal pillars 224 plated in the openings 222 are plated at the same rate, meaning that at any given time, the metal pillars 224 have the same height. The total amount of time to plate the metal pillars 224 such that the distal (i.e., top) ends of the metal pillars 224 are approximately flush with the top surface of the patterned photoresist layer 220 is defined herein as time t₂. The method 50 includes removing the second photoresist layer (76) and etching away portions of the copper seed layer and the titanium tungsten layer (78), as the profile cross-sectional and top-down views of FIGS. 2I1 and 2I2 show.

Because the metal pillars 218 and 224 are plated in openings 216 and 222 (i.e., cavities) of different shapes and/or sizes (e.g., circular vs. ovoid), the speed at which the metal pillars 218 are plated differs from the speed at which the metal pillars 224 are plated. Consequently, the total time t₁ required to plate the metal pillars 218 is different from the total time t₂ required to plate the metal pillars 224. The plating times t₁ and t₂ may be manually (e.g., by an engineer or technician) or automatically (e.g., by a computer) controlled such that, when the metal pillars 218 and 224 are fully plated, the distal (i.e., topmost) ends of the metal pillars 218 and 224 are coplanar or at least approximately coplanar. Furthermore, because the metal pillars 218 and 224 are plated separately (i.e., in separate plating processes), the grain patterns of the metal pillars 218 are similar to each other, and the grain patterns of the metal pillars 224 are similar to each other, but the grain patterns of the metal pillars 218 differ substantially from the grain patterns of the metal pillars 224. The grain pattern in an electroplated metal component refers to the microscopic crystalline structure formed by the orientation, size, and distribution of metal grains as they nucleate and grow during electrodeposition, influenced by plating parameters such as current density, electrolyte composition, and substrate characteristics.

The vertical thicknesses of the metal pillars 218 and 224 range from 10 microns to 80 microns. Thicknesses below this range are disadvantageous because a standoff is necessary to apply any necessary underfill, and thicknesses above this range are disadvantageous because of an unacceptable increase in form factor.

Optionally, the distal ends of the metal pillars 218 and 224 may be plated with tin, silver, or a tin-silver alloy plating 226, as the profile cross-sectional, top-down, and perspective views of FIGS. 2J1-2J3 show. The platings 226 may be plated using techniques similar to those described above, with differently patterned photoresists for the platings 226 on the metal pillars 218 and for the platings 226 on the metal pillars 224. The platings 226 on the metal pillars 218 and 224 are plated in different plating sessions extending for different plating times/durations as described above to facilitate distal ends of the platings 226 that are coplanar or at least approximately coplanar with each other. Consequently, the platings 226 on the metal pillars 218 (e.g., circular) are of a different horizontal cross-sectional shape than the platings 226 on the metal pillars 224 (e.g., ovoid), and the platings 226 on the metal pillars 218 may have a grain pattern that is different from the grain pattern of the platings 226 on the metal pillars 224. The platings 226 may be referred to herein as part of the metal pillars 218 and 224, such that a statement that the metal pillars 218 and 224 have coplanar or approximately coplanar distal ends means that the distal ends of the metal pillars 218 and 224 are coplanar or approximately coplanar, the distal ends of the platings 226 are coplanar or approximately coplanar, and/or a combination thereof. After the platings 226 have been plated, any excess seed layer material is etched away.

The method 50 includes singulating the semiconductor wafer to produce a semiconductor die (80), coupling the first and second copper pillars to conductive terminals by solder bumps (82), and covering the semiconductor die, the first and second copper pillars, the solder bumps, and the conductive terminals with a mold compound (84). FIGS. 2K1-2K3 are profile cross-sectional, top-down, and perspective views of the structure of FIGS. 2J1-2J3, singulated from other parts of the semiconductor wafer to produce an individual semiconductor die 227, and coupled to conductive terminals 228 by solder bumps 230 (e.g., solder balls). The solder bumps 230 have cross-sectional diameters ranging from 100 microns to 600 microns, with a diameter below this range being disadvantageous because of an unacceptable reduction in current carrying ability, and with a diameter above this range being disadvantageous because of an unacceptable increase in form factor. FIGS. 2L1-2L5 are profile cross-sectional, top-down, perspective, perspective, and perspective views of the structure of FIGS. 2K1-2K3, covered with a mold compound 232. The structure of FIGS. 2L1-2L5 is a completed semiconductor package 234 (e.g., a quad flat no lead (QFN) package). The conductive terminals 228 may be of differing shapes, depending on the operation of the conductive terminal 228. For example, larger conductive terminals 228 may be configured to provide power (e.g., high current signals), while smaller conductive terminals 228 may be configured to provide data signals (e.g., low current signals). Similarly, larger metal pillars (e.g., ovoid metal pillars 224) may be coupled to the larger conductive terminals 228, while smaller metal pillars (e.g., circular metal pillars 218) may be coupled to the smaller conductive terminals 228.

In some examples, the structure of FIGS. 2J1-2J3 may be coupled to a substrate. FIGS. 2M1-2M3 are profile cross-sectional, top-down, and perspective views of the structure of FIGS. 2J1-2J3 coupled to a substrate that includes a member 108 (e.g., polyimide, bismaleimide), solder masks 106 and 110 on opposing top and bottom surfaces of the member 108, metal members 124 on the top surface of the member 108, vias 128 extending through the thickness of the member 108 and coupled to the metal members 124, metal members 130 on the bottom surface of the member 108 and coupled to the vias 128, and solder bumps 112 coupled to the metal members 130. The metal members 124 may be coupled to solder bumps 118, which are coupled to the metal pillars 218, 224. The entire structure of FIGS. 2M1-2M3 is a completed semiconductor package 236 (e.g., a ball grid array (BGA) package).

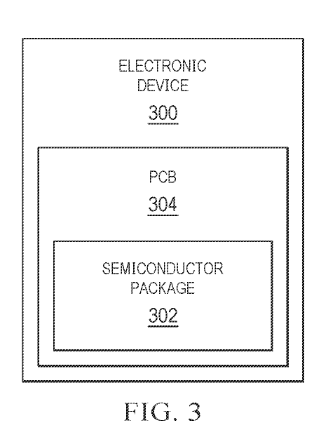

FIG. 3 is a block diagram of an electronic device 300 including a semiconductor package 302 coupled to a PCB 304 and having separately plated metal pillars, in accordance with various examples. For example, the semiconductor package 302 is representative of the semiconductor packages 234 and/or 236.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/- 10 percent of that parameter. Modifications are possible in the described examples, and other examples are possible within the scope of the claims.

As used herein, the terms “terminal,” “node,” “interconnection,” “pin,” “conductive terminal,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A method for manufacturing a semiconductor package, comprising:
forming metal pads on a device side of a semiconductor wafer in which circuitry and metal vias are formed, the metal pads physically contacting the metal vias;
applying a dielectric layer on the metal pads;
forming openings in the dielectric layer above the metal pads;
depositing a seed layer on the dielectric layer and the metal pads;
plating a first set of metal pillars on a first set of the metal pads and separately plating a second set of metal pillars on a second set of the metal pads such that the first set of metal pillars and the second set of metal pillars have distal ends that are coplanar, the first set of metal pillars having a first shape in a top-down view and the second set of metal pillars having a second shape in the top-down view, the second shape different from the first shape;
coupling the first and second sets of metal pillars to conductive terminals; and
applying a mold compound covering the dielectric layer, the first and second sets of metal pillars, and the conductive terminals.

2. The method of claim 1, further comprising plating the first set of pillars for a first duration of time and plating the second set of pillars for a second duration of time, wherein the first and second durations of time differ.

3. The method of claim 1, wherein the first and second sets of metal pillars have vertical thicknesses ranging from 10 microns to 80 microns.

4. The method of claim 1, further comprising plating the first and second sets of metal pillars with tin and/or silver.

5. The method of claim 4, further comprising plating the first set of metal pillars with the tin and/or silver separately from the second set of metal pillars.

6. A method for manufacturing a semiconductor package, comprising:
applying a copper seed layer to a dielectric layer coupled to a device side of a semiconductor wafer, the device side having circuitry formed therein;
patterning a first photoresist layer on the copper seed layer, the first photoresist layer having first openings therein, the first openings having a first shape when viewed in a top-down view;
plating first copper pillars in the first openings using the copper seed layer, the first copper pillars having cross-sectional shapes matching the first shape;
removing the first photoresist layer;
patterning a second photoresist layer on the copper seed layer, the second photoresist layer having second openings therein, the second openings having a second shape when viewed in the top-down view;
plating second copper pillars in the second openings using the copper seed layer, the second copper pillars having cross-sectional shapes matching the second shape;
removing the second photoresist layer;
etching portions of the copper seed layer;
coupling the first and second copper pillars to conductive terminals by solder bumps; and
covering the semiconductor wafer, the first and second copper pillars, the solder bumps, and the conductive terminals with a mold compound.

7. The method of claim 6, further comprising plating the first copper pillars for a first duration of time and plating the second copper pillars for a second duration of time, wherein the first and second durations of time differ.

8. The method of claim 6, further comprising plating tin and/or silver on the first and second copper pillars.

9. The method of claim 6, wherein the first shape is circular and the second shape is oval.

10. The method of claim 6, wherein surfaces of the first and second copper pillars distal from the semiconductor wafer are coplanar.

11. A semiconductor package, comprising:
a semiconductor die having a device side in which circuitry is formed;
a first set of metal pillars on the device side of the semiconductor die having a first structural grain pattern;
a second set of metal pillars on the device side of the semiconductor die having a second structural grain pattern, the second structural grain pattern different from the first structural grain pattern;
a set of conductive terminals coupled to the first and second sets of metal pillars by solder bumps, the set of conductive terminals facing the device side of the semiconductor die; and
a mold compound covering the semiconductor die, the first and second sets of metal pillars, and the set of conductive terminals.

12. The semiconductor package of claim 11, wherein distal surfaces of the first and second sets of metal pillars are coplanar.

13. The semiconductor package of claim 11, wherein the first set of metal pillars have a first horizontal cross-sectional shape and the second set of metal pillars have a second horizontal cross-sectional shape different from the first horizontal cross-sectional shape.

14. The semiconductor package of claim 13, wherein the first horizontal cross-sectional shape is circular and the second horizontal cross-sectional shape is oval.

15. The semiconductor package of claim 11, wherein the semiconductor package is a quad flat no lead (QFN) package.

16. The semiconductor package of claim 11, wherein the semiconductor package is a ball grid array (BGA) package.

17. The semiconductor package of claim 11, further comprising:
first and second horizontal metal members coupled to the device side by way of vias, the first and second horizontal metal members having thicknesses ranging from 4 microns to 25 microns.

18. The semiconductor package of claim 11, wherein the first and second sets of metal pillars have vertical thicknesses ranging from 10 microns to 80 microns.

19. The semiconductor package of claim 11, wherein the solder bumps have vertical thicknesses ranging from 10 microns to 60 microns.

20. The semiconductor package of claim 11, further comprising a dielectric layer physically contacting the device side.

21. The semiconductor package of claim 11, further comprising a tin and/or silver layer on the first and second sets of metal pillars.
